(19) United States
(12) Patent Application Publication
(10) Pub. No.: US 2022/0320269 A1
(43) Pub. Date: Oct. 6, 2022

(54) DISPLAY DEVICE, ARRAY SUBSTRATE, THIN FILM TRANSISTOR AND FABRICATION METHOD THEREOF

(71) Applicants: Chengdu BOE Optoelectronics Technology Co., Ltd., Sichuan (CN); BOE TECHNOLOGY GROUP CO., LTD., Beijing (CN)

(72) Inventors: Bingqiang GUI, Beijing (CN); Ke LIU, Beijing (CN); Peng HUANG, Beijing (CN); Tao GAO, Beijing (CN)

(21) Appl. No.: 17/424,576

(22) PCT Filed: Jan. 4, 2021
(86) PCT No.: PCT/CN2021/070122

§ 371 Date: Jul. 21, 2021

(30) Foreign Application Priority Data
Jan. 20, 2020 (CN) 202010066864.9

(51) Int. Cl. H01L 29/06; H01L 27/12; H01L 29/423; H01L 29/40; H01L 29/66; H01L 29/786

(52) U.S. Cl. CPC H01L 29/0607; H01L 27/127; H01L 27/1225; H01L 29/42384; H01L 29/401; H01L 29/66742; H01L 29/7869; H01L 29/78696; H01L 27/1288; H01L 29/41733

(57) ABSTRACT

This disclosure provides a display device, an array substrate, a thin film transistor and a fabrication method thereof. The thin film transistor includes an active layer, a gate insulating layer, a gate electrode, a dielectric layer, a source electrode and a drain electrode. The active layer has a channel region, doped regions at both sides of the channel region, and buffer regions each of which arranged between the corresponding doped region and the channel region, and a doping concentration of the buffer regions is less than that of the doped regions. The gate insulating layer is at a side of the active layer, covers the channel region and the buffer regions, and exposes the doped regions. The gate electrode is on a surface of the gate insulating layer facing away from the active layer.

### CROSS-REFERENCE TO RELATED APPLICATIONS

This disclosure claims priority to the Chinese patent application No. 202010066864.9, filed on Jan. 20, 2020, and entitled “DISPLAY DEVICE, ARRAY SUBSTRATE, THIN FILM TRANSISTOR AND FABRICATION METHOD THEREOF”, the entire contents of which are hereby incorporated by reference.

### TECHNICAL FIELD

The present disclosure relates to the technical field of display, in particular to a display device, an array substrate, a thin film transistor and a fabrication method of a thin film transistor.

### BACKGROUND

In the display panel, a thin film transistor (TFT) is an important circuit device for driving pixels to emit light. The existing TFT is generally divided into two types: a bottom-gate structure and a top-gate structure, and the top-gate structure is widely used. However, after the fabrication of the thin film transistor is completed, the display panel still needs to experience other subsequent processes, in which some of high temperature processes may cause a threshold voltage drift of the thin film transistor, and lead to uneven light emission of the display panel and the like, in particular, for an OLED (Organic Light-Emitting Diode) display panel, the threshold voltage drift is typically serious.

It should be noted that the information disclosed in the above “Background” section is merely intended to reinforce understanding of the background technology of the present disclosure, accordingly the Background may include information that does not constitute the prior art as already known by an ordinary person skilled in the art.

### SUMMARY

An objection of this disclosure is to overcome the shortcomings of the prior art and to provide a display device, an array substrate, a thin film transistor and a fabrication method of a thin film transistor.

According to an aspect of the present disclosure, a thin film transistor is provided. The thin film transistor includes:

an active layer having a channel region, doped regions on both sides of the channel region, and buffer regions each of the buffer regions arranged between a corresponding one of the doped regions and the channel region, wherein a doping concentration of the buffer regions is less than that of the doped region;

a gate insulating layer arranged at a side of the active layer, covering the channel region and the buffer regions, and exposing the doped regions;

a gate electrode arranged on a surface of the gate insulating layer facing away from the active layer, in which a projection of the gate electrode on the active layer is overlapped with the channel region;

a dielectric layer covering the gate electrode, the gate insulating layer and the active layer;

a source electrode and a drain electrode arranged on a surface of the dielectric layer facing away from the active layer and located at both sides of the channel region, in which the source electrode and the drain electrode are respectively connected to different doped regions.

In an exemplary embodiment of the present disclosure, the buffer regions include a first buffer region and a second buffer region symmetrically distributed at the both sides of the channel region.

In an exemplary embodiment of the present disclosure, a material of the active layer includes metal oxide.

In an exemplary embodiment of the present disclosure, the buffer region has a width of 0.5 μm-1.5 μm.

According to one aspect of the present disclosure, a fabrication method of a thin film transistor is provided. The fabrication method includes steps of:

forming an active layer at a side of a base, in which the active layer includes a channel region, to-be-doped regions at both sides of the channel region, and a buffer region each of the buffer regions arranged between a corresponding one of the to-be-doped regions and the channel region;

forming a gate insulating layer and a gate electrode at a side of the active layer facing away from the base, in which the gate insulating layer covers the channel region and the buffer regions and exposes the to-be-doped regions; the gate electrode is positioned on a surface of the gate insulating layer facing away from the base, and a projection of the gate electrode on the active layer is overlapped with the channel region;

doping the to-be-doped regions to form doped regions, in which a doping concentration of the buffer regions is less than that of the doped regions;

forming a dielectric layer covering the gate electrode, the gate insulating layer and the doped regions;

forming a source electrode and a drain electrode on a surface of the dielectric layer facing away from the active layer, in which the source electrode and the drain electrode are located at both sides of the channel region and are respectively connected to different doped regions.

In an exemplary embodiment of the present disclosure, the step of forming a gate insulating layer and a gate electrode at a side of the active layer facing away from the base, includes steps of:

sequentially laminating the gate insulating layer and a gate metal layer on a surface of the active layer facing away from the base, in which the gate insulating layer has a projection overlapped with that of the gate metal layer on the active layer, covers the buffer regions and the channel region, and exposes the to-be-doped regions;

patterning the gate metal layer to form a gate electrode, in which a projection of the gate electrode on the active layer is overlapped with the channel region.

In an exemplary embodiment of the present disclosure, the step of patterning the gate metal layer includes steps of:

forming a photoresist layer covering the to-be-doped regions at a side of the active layer facing away from the base, in which the photoresist layer exposes the gate metal layer;

etching the gate metal layer to form a gate electrode, in which a projection of the gate electrode on the active layer is overlapped with the channel region.

In an exemplary embodiment of the present disclosure, the step of forming a photoresist layer covering the to-be-doped regions at a side of the active layer facing away from the base includes steps of:

forming a photoresist layer covering the to-be-doped regions at a side of the active layer facing away from the substrate;

ashing the photoresist layer to expose the gate metal layer, in which a thickness of the photoresist layer is not less than that of the gate insulating layer;

the step of etching the gate metal layer to form a gate electrode, including a step of:

etching the gate metal layer with an etching solution so that a projection of the gate metal layer on the active layer is overlapped with the channel region to obtain a gate electrode.

In an exemplary embodiment of the present disclosure, the step of forming a gate insulating layer and a gate electrode at a side of the active layer facing away from the substrate, includes steps of:

forming a gate insulating layer on a surface of the active layer facing away from the base, in which the gate insulating layer covers the channel region and the buffer regions and exposes the to-be-doped regions;

forming a gate electrode on a surface of the gate insulating layer facing away from the base, in which a projection of the gate electrode on the active layer is overlapped with the channel region.

In an exemplary embodiment of the present disclosure, the step of forming a gate insulating layer on a surface of the active layer facing away from the base, includes steps of:

depositing an insulating material layer covering the active layer and the base;

patterning the insulating material layer by using a mask process to obtain a gate insulating layer, in which the gate insulating layer covers the channel region and the buffer regions and exposes the to-be-doped regions;

the step of forming a gate electrode on a surface of the gate insulating layer facing away from the base, includes steps of:

depositing a gate metal layer covering the gate insulating layer and the active layer;

patterning the gate metal layer by using a mask process to obtain a gate electrode, in which a projection of the gate electrode on the active layer is overlapped with the channel region.

In an exemplary embodiment of the present disclosure, a material of the active layer includes metal oxide; the step of doping the to-be-doped regions includes a step of:

conducting the to-be-doped regions to form doped regions.

In an exemplary embodiment of the present disclosure, the buffer regions include a first buffer region and a second buffer region symmetrically distributed at both sides of the channel region.

According to an aspect of the present disclosure, an array substrate including the thin film transistor described in any one of the above embodiments is provided.

According to an aspect of the present disclosure, a display device including the array substrate described in any one of the above embodiments is provided.

It should be understood that both the foregoing general description and the following detailed description are exemplary and explanatory only and are not restrictive of the disclosure.

### BRIEF DESCRIPTION OF THE DRAWINGS

The accompanying drawings, which are incorporated in and constitute part of this specification, illustrate embodiments consistent with the invention and, together with the description, serve to explain the principles of the invention. Apparently, the drawings in the following description are only for illustrating some embodiments of the present disclosure and those of ordinary skill in the art can also derive other drawings based on the drawings without paying any creative labor.

FIG. 1 is a schematic view of an Id-Vg curve of a thin film transistor in the related art.

FIG. 2 is a schematic view of an embodiment of a thin film transistor of the present disclosure.

FIG. 3 is a schematic view of the Id-Vg curve of a thin film transistor of the present disclosure.

FIG. 4 is a flowchart of an embodiment of a fabrication method of the present disclosure.

FIG. 5 is a schematic view of step S110 in an embodiment of a fabrication method of the present disclosure.

FIG. 6 is a schematic view of step 5120 in an embodiment of a fabrication method of the present disclosure.

FIG. 7 is a schematic view of step S120 in another embodiment of a fabrication method of the present disclosure.

FIG. 8 is a schematic view of step 5140 in an embodiment of a fabrication method of the present disclosure.

### LIST OF REFERENCE NUMBERS

1: active layer; 11: channel region; 12: doped region; 121: first doped region; 122: second doped region; 13: buffer region; 131: first buffer region; 132: second buffer region; 2: gate insulating layer; 3: gate electrode; 4: dielectric layer; 5: source electrode; 6: drain electrode; 7: base; 8: buffer layer; 100: gate metal layer; 101: to-be-doped region; 200: photoresist layer.

### DETAILED DESCRIPTION

Exemplary embodiments will now be described more fully by reference to the accompanying drawings. However, the exemplary embodiments can be implemented in various forms and should not be understood as being limited to the examples set forth herein; rather, the embodiments are provided so that this disclosure will be thorough and complete, and the conception of exemplary embodiments will be fully conveyed to those skilled in the art. The same reference signs in the drawings denote the same or similar structures and detailed description thereof will be omitted. In addition, the drawings are merely schematic illustrations of the present disclosure and are not necessarily drawn to scale.

Although relative terms such as “above” and “under” are used herein to describe the relationship of one component relative to another component, such terms are used herein only for the sake of convenience, for example, in the direction shown in the figure, it should be understood that if the referenced device is inversed upside down, a component described as “above” will become a component described as “under”. When a structure is described as “above” another structure, it probably means that the structure is integrally formed on another structure, or, the structure is “directly” disposed on another structure, or, the structure is “indirectly” disposed on another structure through an additional structure.

The terms “a”, “an”, “the”, “said” and “at least one”, are used to express the presence of one or more the element/ constitute/ or the like. The terms “comprise”, “include” and “have” are intended to be inclusive, and mean there may be additional elements/constituents/ or the like other than the listed elements/ constituents/ or the like. The “first” and “second” are used only as marks, and are not numerical restriction to the objects.

In the related art, a thin film transistor is an essential circuit device for an OLED display device and a liquid crystal display device. After the thin film transistor is formed, for example, after source and drain electrodes are formed, it is required to experience some high-temperature processes, for example, high-temperature processes such as passivation are required for a liquid crystal display device, and high temperature processes such as passivation, planarization and packaging are required for an OLED display device. In these high-temperature processes, the final characteristic (Final EPM) of the thin film transistor generates a deviation from the device characteristic (SD EPM) after the source and drain electrodes are completed, since carriers in the doped region of the active layer of the thin film transistor can diffuse to the channel region due to the high temperature, resulting in a Vth negatively shift of the threshold voltage. Since there are a lot of high-temperature processes for the OLED display device, the phenomenon of the Vth negatively shift of the threshold voltage is more serious.

For example, as shown in FIG. 1, 51 in FIG. 1 shows the Id-Vg curve of the thin film transistor after completion of the thin film transistor (i.e., after the source and drain electrodes are formed), for reflecting the device characteristic after the completion of the source and drain electrodes, i.e., SD EPM; S2 in FIG. 1 shows the Id-Vg curve of the thin film transistor after fabrication of the display device, for reflecting the Final EPM of the thin film transistor. It can be seen from the curves 51 and S2 that compared with 51, the threshold voltage Vth of S2 generates a larger Vth negatively drift.

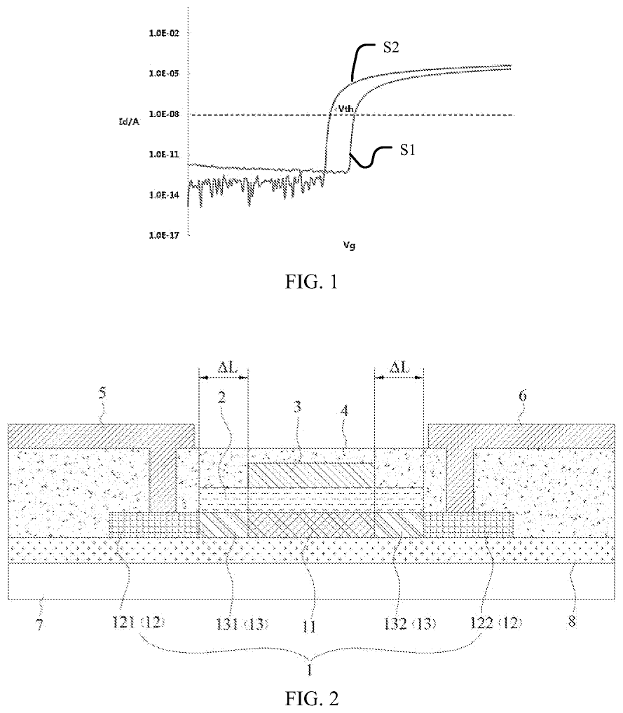

The embodiment of the present disclosure provides a thin film transistor which can be used in a liquid crystal display device or an OLED display device. As shown in FIG. 2, the thin film transistor includes an active layer 1, a gate insulating layer 2, a gate electrode 3, a dielectric layer 4, a source electrode 5 and a drain electrode 6.

The active layer 1 has a channel region 11, doped regions 12 at both sides of the channel region 11, and buffer regions 13. Each of the buffer regions is arranged between a corresponding one of the doped regions 12 and the channel region 11, and a doping concentration of the buffer regions 13 is less than that of the doped regions 12. The gate insulating layer 2 is disposed at a side of the active layer 1, covers the channel region 11 and the buffer regions 13, and exposes the doped regions 12. The gate electrode 3 is arranged on a surface of the gate insulating layer 2 facing away from the active layer 1, and a projection of the gate electrode 3 on the active layer 1 is overlapped with the channel region 11. A dielectric layer 4 covers the gate electrode 3, the gate insulating layer 2 and the active layer 1. The source electrode 5 and the drain electrode 6 are arranged on a surface of the dielectric layer 4 facing away from the active layer 1, located at both sides of the channel region 11, and are respectively connected to different doped regions 12.

In the thin film transistor according to the embodiment of the present disclosure, since a coverage area of the gate insulating layer 2 is larger than that of the channel region 11, after the doped regions 12 are formed, the buffer regions 13 separating the channel region 11 and the doped regions 12 is formed. After the thin film transistor is fabricated, as performing packaging and other processes of the display device that require high temperature, carriers in the doped region 12 may diffuse to the channel region 11, that is, the doped impurities may diffuse to the channel region 11. At this time, the buffer region 13 blocks the carriers of the doped region 12 from entering the channel region 11, to reduce the carriers entering the channel region 11, avoid the reduction of a length of the channel region 11, and prevent a negative drift of the threshold voltage, without affecting an ohmic contact of the doped region, protect the semiconductor characteristics of the channel region 11 from being affected, and avoid the short channel effect. After the display device is fabricated, a carrier concentration of the buffer regions 13 is less than that of the doped regions 12 but greater than that of the channel region 11, that is, a doping concentration of the buffer regions 13 is between the channel region 11 and the doped regions 12.

For example, as shown in FIG. 3, Si in FIG. 3 shows the Id-Vg curve of the thin film transistor after the thin film transistor is completed, that is, after the source and drain electrodes are formed; S2 in FIG. 3 shows the Id-Vg curve of the thin film transistor after the display device is fabricated. It can be seen from the curves Si and S2 in FIG. 3 that the negative drift of the threshold voltage Vth is obviously less than the negative drift in the related art in FIG. 1.

The respective parts of the thin film transistor according to the embodiment of the present disclosure will be described in detail below.

As shown in FIG. 2, the active layer 1 has a channel region 11 and doped regions 12 at both sides of the channel region 11, meanwhile, the doped regions 12 are separated from the channel region 11 by the buffer regions 13, and a doping concentration of the buffer regions 13 is less than that of the doped regions 12, so that the carrier concentration in the buffer regions 13 is less than a carrier concentration of the doped regions 12. The buffer region 13 can be understood as an extension of channel region 11. Since the gate electrode 3 only corresponds to the channel region 11 instead of the buffer region 13, the buffer region 13 does not serve as the channel region 11, but only used to block carrier from diffusing to channel region 11. A width ΔL of the buffer region 13 may be 0.5 μm-1.5 μm, for example, 0.5 μm, 1 μm or 1.5 μm. The width ΔL of the buffer region 13 may be a distance between the channel region 11 and the doped region 12.

It should be noted that carriers i.e., doped impurities in the buffer region 13 diffuse to the buffer region 13 in other high-temperature processes such as packaging of the display device after the thin film transistor is fabricated, rather than specially formed in the buffer region 13 when the thin film transistor is formed.

The material of the active layer 1 may include metal oxides, such as indium gallium zinc oxide (IGZO), indium zinc oxide (IZO), zinc oxide (ZnO) or the like. Of course, other materials may also be used for the active layer 1. Meanwhile, the doped region 12 may be a N-type doped region, and the thin film transistor may be an N-type thin film transistor. Alternatively, the doped region 12 may be a P-type doped region, and the thin film transistor may be a P-type thin film transistor.

In some embodiments of the present disclosure, as shown in FIG. 2, the doped region 12 includes a first doped region 121 and a second doped region 122 symmetrically distributed at both sides of the channel region 11. Meanwhile, the buffer regions 13 may include a first buffer region 131 and a second buffer region 132 symmetrically distributed at both sides of the channel region 11. The first buffer region 131 is arranged between the first doped region 121 and the channel region 11, and the second buffer region 132 is arranged between the second doped region 122 and the channel region 11.

As shown in FIG. 2, the material of the gate insulating layer 2 may include insulating materials such as silicon oxide and silicon nitride. The gate insulating layer may be disposed at a side of the active layer 1 and cover the channel region 11 and the buffer regions 13, that is, an area of the gate insulating layer 2 is larger than that of the channel region 11. An edge of the gate insulating layer may be aligned with an edge of the buffer region 13, and the gate insulating layer 2 exposes the doped region 12.

As shown in FIG. 2, the gate electrode 3 is provided on a surface of the gate insulating layer 2 facing away from the active layer 1, and a projection of the gate electrode 3 on the active layer 1 is overlapped with the channel region 11, that is, an edge of the projection of the gate electrode 3 on the active layer 1 coincides with (i.e., overlapped with) an edge of the channel region 11, and both the buffer regions 13 and the doped regions 12 are located outside the gate electrode 3. The material of the gate electrode 3 may include metals such as molybdenum, which is not particularly limited herein.

As shown in FIG. 2, the dielectric layer 4 is made of an insulating layer material and covers the gate electrode 3, the gate insulating layer 2 and the active layer 1, that is, the dielectric layer 4 covers the gate electrode 3, a region of the gate insulating layer 2 uncovered by the gate electrode 3, and the doped layer 12.

As shown in FIG. 2, the source electrode 5 and the drain electrode 6 are arranged on the surface of the dielectric layer 4 facing away from the active layer 1 and located at both sides of the channel region 11. The source electrode 5 is connected to the corresponding doped region 12 through a via hole passing through the dielectric layer 4, and the drain electrode 6 is connected to the corresponding doped region 12 through a via hole passing through the dielectric layer 4. The source electrode 5 and the drain electrode 6 are connected to different doped regions 12. For example, the source electrode 5 may be connected to the first doped region 121 through a first via hole passing through the dielectric layer 4, and the drain electrode 6 may be connected to the second doped region 122 through a second via hole passing through the dielectric layer 4.

Further, as shown in FIG. 2, in some embodiments of the present disclosure, the thin film transistor may further include a base 7 and a buffer layer 8.

The base 7 may be made of glass or other transparent materials. The buffer layer 8 may be arranged at a side of the base 7, and may be made of silicon oxide, silicon nitride, and the like. The active layer 1 may be arranged on a surface of the buffer layer 8 facing away from the base 7, and impurities in the base 7 can be blocked from entering the active layer 1 through the buffer layer 8.

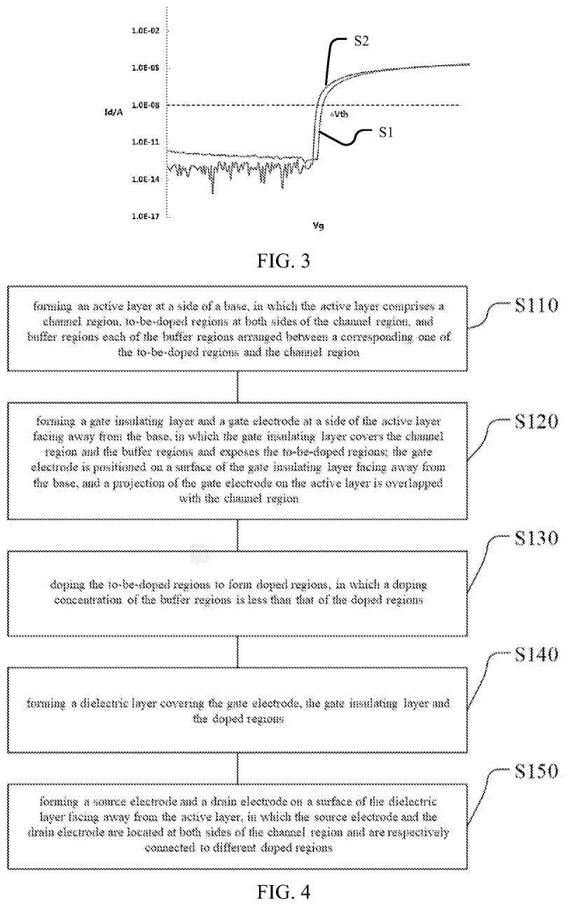

An embodiment of the present disclosure provides a fabrication method of a thin film transistor, in which the thin film transistor may be any of the above-mentioned thin film transistors, and its structure will not be described in detail herein. As shown in FIG. 4, the fabrication method of the present disclosure includes steps S110- S150.

Step S110, forming an active layer at a side of a base, in which the active layer has a channel region, to-be-doped regions at both sides of the channel region, and buffer regions each of the buffer regions arranged between a corresponding one of the to-be-doped regions and the channel region.

Step S120, forming a gate insulating layer and a gate electrode at a side of the active layer facing away from the base, in which the gate insulating layer covers the channel region and the buffer regions and exposes the to-be-doped regions, the gate electrode is located on a surface of the gate insulating layer facing away from the base, and a projection of the gate electrode on the active layer is overlapped with the channel region.

Step S130, doping the to-be-doped regions to form doped regions, in which a doping concentration of the buffer regions is less than that of the doped regions.

Step S140, forming a dielectric layer covering the gate electrode, the gate insulating layer and the doped regions.

Step S150, forming a source electrode and a drain electrode on a surface of the dielectric layer facing away from the active layer, in which the source electrode and the drain electrode are located at both sides of the channel region, and are respectively connected to different doped regions.

The beneficial effects of the fabrication method according to the embodiment of the present disclosure can refer to the beneficial effects in the embodiment of the thin film transistor mentioned above, and will not be described in detail herein.

The steps of the fabrication method according to the embodiment of the present disclosure will be described in detail below.

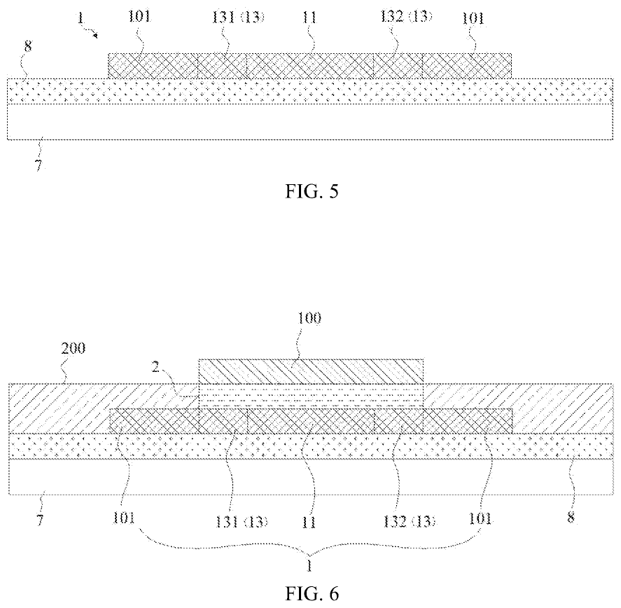

In the step S110, as shown in FIG. 5, the base 7 may be made of glass or other transparent materials. The active layer 1 has a channel region 11 and to-be-doped regions 101 located at both sides of the channel region 11. Meanwhile, the to-be-doped regions 101 and the channel region 11 are separated by the buffer regions 13. The material of the active layer 1 may include metal oxides, such as indium gallium zinc oxide (IGZO), indium zinc oxide (IZO), zinc oxide (ZnO), or the like, and the active layer 1 may be formed by magnetron sputtering, or the like. Of course, the active layer 1 may also be made of other materials, which is not limited to metal oxides.

It should be noted that in the step S110, the active layer 1 is not the active layer, and the channel region 11, the to-be-doped regions 101 and the buffer regions 13, which are finally required, but only different regions of the active layer 1. The to-be-doped regions 101 may be doped by a doping process to form doped regions 12.

Further, as shown in FIG. 5, in some embodiments of the present disclosure, in order to prevent impurities in the base 7 from entering the active layer 1, the buffer layer 8 may be formed at a side of the base 7, and then the active layer 1 may be formed on a surface of the buffer layer 8 facing away from the base 7. The material of the buffer layer 8 may include silicon oxide, silicon nitride and the like.

In the step S120, as shown in FIG. 2, the structures of the gate insulating layer 2 and the gate electrode 3 may refer to those of the thin film transistor, and will not be described in detail herein.

In some embodiments of the present disclosure, the gate insulating layer and the gate electrode are formed at a side of the active layer facing away from the substrate, that is, the step S120 may include step S1210 and step S1220.

In the step S1210, i.e., sequentially laminating a gate insulating layer and a gate metal layer on the surface of the active layer facing away from the substrate, the gate insulating layer has a projection overlapped with that of the gate metal layer on the active layer, covers the buffer regions and the channel region, and exposes the to-be-doped regions.

As shown in FIG. 6, edges of the gate insulating layer 2 and the gate metal layer 100 are aligned with edges of the buffer regions 13 in a direction perpendicular to the base 7, and the edges of the gate insulating layer 2 and the gate metal layer 100 are overlapped, so that the gate insulating layer 2 and the gate metal layer 100 may be formed by one patterning process to simplify the process. For example, the gate insulating layer 2 and the gate metal layer 100 may be formed by a self-aligning process.

In the step S1220, i.e., patterning the gate metal layer to form a gate electrode, the projection of the gate electrode on the active layer is overlapped with the channel region.

As shown in FIG. 2, an area of the gate electrode 3 is smaller than that of the gate insulating layer 2, and the edge of the gate electrode 3 is aligned with the edge of the channel region 11 of the active layer 1 in the direction perpendicular to the base 7.

In some embodiments of the present disclosure, patterning the gate metal layer, i.e., the step S1220, including step S12210 and step S12220.

In the step S12210, a photoresist layer covering the to-be-doped regions is formed at a side of the active layer facing away from the base, and the photoresist layer exposes the gate metal layer.

As shown in FIG. 6, the photoresist layer 200 may be made of photoresist, and may be configured to cover the to-be-doped regions 101, and may further cover a region of the buffer layer 8 uncovered by the active layer 1. Meanwhile, the photoresist layer 200 exposes the gate metal layer 100, so that patterning processes such as etching may be performed on the gate metal layer 100.

In some embodiments of the present disclosure, the step S12210 may include:

step S122110: forming a photoresist layer covering the to-be-doped regions at a side of the active layer facing away from the base; and

step S122120: ashing the photoresist layer to expose the gate metal layer, in which a thickness of the photoresist layer is not less than a thickness of the gate insulating layer.

The photoresist layer may be gradually thinned by the ashing process until the gate metal layer is exposed.

In the step S12220, the gate metal layer is etched to form a gate electrode, and the projection of the gate electrode on the active layer is overlapped with the channel region.

As shown in FIG. 6, the gate metal layer 100 may be etched by wet etching or other methods to obtain the gate electrode 3. The structure of the gate electrode 3 may refer to the above exemplary description and will not be described in detail herein.

In some embodiments of the present disclosure, the step of etching the gate metal layer to form a gate electrode includes:

etching the gate metal layer with an etching solution so that a projection of the gate metal layer on the active layer is overlapped with the channel region to obtain a gate electrode.

The edge of the gate metal layer may be gradually etched by the etching solution, so that the area of the gate metal layer is gradually reduced until its projection on the active layer 1 is overlapped with the channel region 11, thereby obtaining the gate electrode 3.

In another embodiment of the present disclosure, forming a gate insulating layer and a gate at a side of the active layer facing away from the base, i.e., the step S120 including step S1210 and step S1220.

In the step S1210, i.e., forming a gate insulating layer on a surface of the active layer facing away from the base, the gate insulating layer covers the channel region and the buffer regions and exposes the to-be-doped regions.

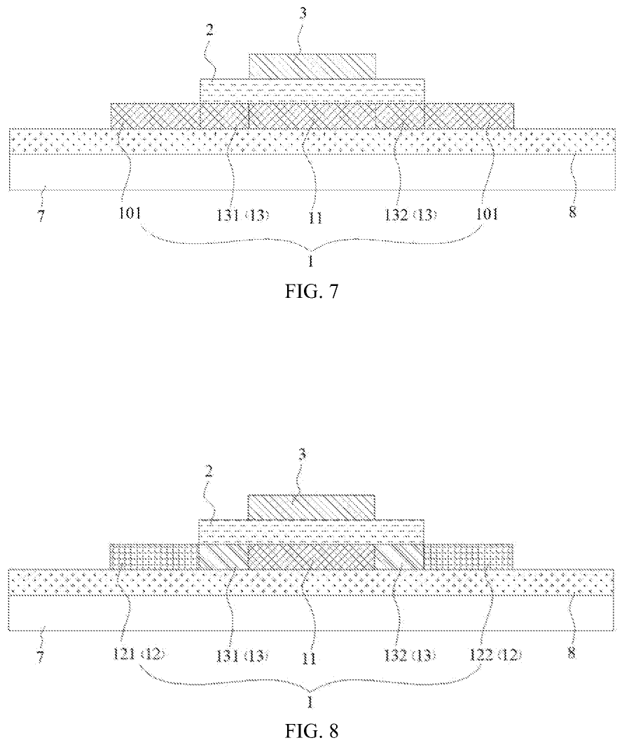

As shown in FIG. 7, the gate insulating layer 2 may be formed on the surface of the active layer 1 facing away from the base 7 by a mask process or other patterning process. The region covered by the gate insulating layer 2 is larger than the channel region 11, that is, both the channel region 11 and the buffer regions 13 are covered. For example, the step S1210 of this embodiment may include:

step S12110, depositing an insulating material layer covering the active layer and the base; and

step S12120, patterning the insulating material layer by using a mask process to obtain a gate insulating layer, in which the gate insulating layer covers the channel region and the buffer regions and exposes the to-be-doped regions.

The mask process of the insulating material layer may include photoresist coating, exposure, development, etching or the like, which will not be described in detail herein.

In the step S1220, a gate electrode is formed on a surface of the gate insulating layer facing away from the base, in which the projection of the gate electrode on the active layer is overlapped with the channel region.

As shown in FIG. 7, the gate electrode 3 may be formed on the surface of the gate insulating layer 2 facing away from the base 7 by a mask process or other patterning process. For example, the step S1220 of this embodiment may include:

step S12210, depositing a gate metal layer covering the gate insulating layer and the active layer; and

step S12220, patterning the gate metal layer by a mask process to obtain a gate electrode, in which the projection of the gate electrode on the active layer is overlapped with the channel region.

The mask process of the gate metal layer may include photoresist coating, exposure, development, etching or the like, which will not be described in detail herein.

In the step S130, the structure of the doped region 12 may refer to the doped region 12 in the above embodiment of the thin film transistor, as shown in FIG. 8, and will not be described in detail herein.

In some embodiments of the present disclosure, the material of the active layer 1 includes metal oxides, such as indium gallium zinc oxide. Doping the to-be-doped regions 101, i.e., step S130, includes:

conducting the to-be-doped regions to form doped regions.

The to-be-doped regions 101 may be bombarded by plasma to form the doped regions 12, so as to realize the conductivity, that is, to realize the doping of the doped regions 12. For example, the doped regions 101 may be bombarded by using hydrogen as a reactive gas and using inert gas as a protective gas to form the doped regions 12.

The doping type of the doped region 12 may be N-type doping. Due to the shielding of the gate insulating layer 2, the doped regions 12 and the channel region 11 are separated by buffer regions 13 after doping, so that the carriers that will enter the channel region 11 may be reduced by the buffer regions 13.

In the step S140, a dielectric layer covering the gate electrode, the gate insulating layer and the doped regions are formed.

As shown in FIG. 2, the dielectric layer 4 is made of insulating layer material and covers the gate electrode 3, the gate insulating layer 2 and the active layer 1, that is, the dielectric layer 4 covers the gate electrode 3, a region of the gate insulating layer 2 uncovered by the gate electrode 3, and the doped regions 12. In order to facilitate connecting the source electrode 5 and the drain electrode 6 with the doped regions 12, via holes for exposing the doped regions 12 may be formed on the dielectric layer 4.

In the step S150, a source electrode and a drain electrode are formed on a surface of the dielectric layer facing away from the active layer, and the source electrode and the drain electrode are located at both sides of the channel region and connected to different doped regions.

As shown in FIG. 2, the structures of the source electrode 5 and the drain electrode 6 may refer to the source electrode 5 and the drain electrode 6 in the above embodiment of the thin film transistor, and will not be described in detail herein.

It should be noted that although the steps of the method in the present disclosure are described in a specific order in the drawings, it is not required or implied that these steps must be performed in the specific order, or that all the steps shown must be performed to achieve desired results. Additionally or alternatively, some of the steps may be omitted, multiple steps may be combined into one step to be performed, and/or one step may be decomposed into multiple steps to be performed.

An embodiment of the present disclosure provides an array substrate including the thin film transistors according to any one of the above embodiments, and the structure of any of the thin film transistors will not be described in detail herein. The array substrate may be used for a liquid crystal display device and an OLED display device, and the beneficial effects may refer to those of the thin film transistors.

An embodiment of the present disclosure also provides a display device including the array substrate of the above embodiments. The display device may be used for a mobile phone, a tablet computer, an electronic paper, an electronic picture screen, a television and other electronic devices, and will not be listed herein.

Other embodiments of the invention will be apparent to those skilled in the art from consideration of the specification and practice of the invention disclosed here. This application is intended to cover any variations, uses, or adaptations of the invention following the general principles thereof and including such departures from the present disclosure as come within known or customary practice in the art. It is intended that the specification and examples be considered as exemplary only, with a true scope and spirit of the invention being indicated by the following claims.

1. A thin film transistor, comprising:
an active layer having a channel region, doped regions on both sides of the channel region, and buffer regions, each of the buffer regions arranged between a corresponding one of the doped regions and the channel region, wherein a doping concentration of the buffer regions is less than a doping concentration of the doped regions;
a gate insulating layer arranged at a side of the active layer, covering the channel region and the buffer regions, and exposing the doped regions;
a gate electrode arranged on a surface of the gate insulating layer facing away from the active layer, wherein a projection of the gate electrode on the active layer is overlapped with the channel region;
a dielectric layer covering the gate electrode, the gate insulating layer and the active layer;
a source electrode and a drain electrode arranged on a surface of the dielectric layer facing away from the active layer and located at both sides of the channel region, wherein the source electrode and the drain electrode are respectively connected to different doped regions.

2. The thin film transistor according to claim 1, wherein the buffer regions comprise a first buffer region and a second buffer region symmetrically distributed at the both sides of the channel region.

3. The thin film transistor according to claim 1, wherein a material of the active layer comprises metal oxide.

4. The thin film transistor according to claim 1, wherein the buffer region has a width of 0.5 μm-1.5 μm.

5. A fabrication method of a thin film transistor, comprising steps of:
forming an active layer at a side of a base, in which the active layer comprises a channel region, to-be-doped regions at both sides of the channel region, and buffer regions each of the buffer regions arranged between a corresponding one of the to-be-doped regions and the channel region;
forming a gate insulating layer and a gate electrode at a side of the active layer facing away from the base, in which the gate insulating layer covers the channel region and the buffer regions and exposes the to-be-doped regions; the gate electrode is positioned on a surface of the gate insulating layer facing away from the base, and a projection of the gate electrode on the active layer is overlapped with the channel region;
doping the to-be-doped regions to form doped regions, in which a doping concentration of the buffer regions is less than that of the doped regions;
forming a dielectric layer covering the gate electrode, the gate insulating layer and the doped regions;
forming a source electrode and a drain electrode on a surface of the dielectric layer facing away from the active layer, in which the source electrode and the drain electrode are located at both sides of the channel region and are respectively connected to different doped regions.

6. The fabrication method according to claim 5, wherein the step of forming a gate insulating layer and a gate electrode at a side of the active layer facing away from the base, comprises steps of:
sequentially laminating the gate insulating layer and a gate metal layer on a surface of the active layer facing away from the base, in which the gate insulating layer has a projection overlapped with that of the gate metal layer on the active layer, covers the buffer regions and the channel region, and exposes the to-be-doped regions;
patterning the gate metal layer to form a gate electrode, in which a projection of the gate electrode on the active layer is overlapped with the channel region.

7. The fabrication method according to claim 6, wherein the step of patterning the gate metal layer comprises steps of:
forming a photoresist layer covering the to-be-doped regions at a side of the active layer facing away from the base, in which the photoresist layer exposes the gate metal layer;
etching the gate metal layer to form a gate electrode, in which a projection of the gate electrode on the active layer is overlapped with the channel region.

8. The fabrication method according to claim 7, wherein the step of forming a photoresist layer covering the to-be-doped regions at a side of the active layer facing away from the base, comprises steps of:
forming a photoresist layer covering the to-be-doped regions at a side of the active layer facing away from the substrate;
ashing the photoresist layer to expose the gate metal layer, in which a thickness of the photoresist layer is not less than that of the gate insulating layer;
the step of etching the gate metal layer to form a gate electrode, comprising a step of:
etching the gate metal layer with an etching solution so that a projection of the gate metal layer on the active layer is overlapped with the channel region to obtain a gate electrode.

9. The fabrication method according to claim 5, wherein the step of forming a gate insulating layer and a gate electrode at a side of the active layer facing away from the substrate, comprises steps of:
forming a gate insulating layer on a surface of the active layer facing away from the base, in which the gate insulating layer covers the channel region and the buffer regions and exposes the to-be-doped regions;
forming a gate electrode on a surface of the gate insulating layer facing away from the base, in which a projection of the gate electrode on the active layer is overlapped with the channel region.

10. The fabrication method according to claim 9, wherein the step of forming a gate insulating layer on a surface of the active layer facing away from the base, comprises steps of:
depositing an insulating material layer covering the active layer and the base;
patterning the insulating material layer by using a mask process to obtain a gate insulating layer, in which the gate insulating layer covers the channel region and the buffer regions and exposes the to-be-doped regions;
the step of forming a gate electrode on a surface of the gate insulating layer facing away from the base, comprises steps of:
depositing a gate metal layer covering the gate insulating layer and the active layer;
patterning the gate metal layer by using a mask process to obtain a gate electrode, in which a projection of the gate electrode on the active layer is overlapped with the channel region.

11. The fabrication method according to claim 5, wherein a material of the active layer comprises metal oxide; the step of doping the to-be-doped regions comprises a step of: conducting the to-be-doped regions to form doped regions.

12. The fabrication method according to claim 5, wherein the buffer regions comprise a first buffer region and a second buffer region symmetrically distributed at both sides of the channel region.

13. An array substrate comprising a thin film transistor wherein the thin film transistor comprises:
an active layer having a channel region, doped regions on both sides of the channel region, and buffer regions, each of the buffer regions arranged between a corresponding one of the doped regions and the channel region, wherein a doping concentration of the buffer regions is less than that of the doped regions;
a gate insulating layer arranged at a side of the active layer, covering the channel region and the buffer regions, and exposing the doped regions;
a gate electrode arranged on a surface of the gate insulating layer facing away from the active layer, in which a projection of the gate electrode on the active layer is overlapped with the channel region;
a dielectric layer covering the gate electrode, the gate insulating layer and the active layer;
a source electrode and a drain electrode arranged on a surface of the dielectric layer facing away from the active layer and located at both sides of the channel region, in which the source electrode and the drain electrode are respectively connected to different doped regions.

14. (canceled)

15. The array substrate according to claim 13, wherein the buffer regions comprise a first buffer region and a second buffer region symmetrically distributed at the both sides of the channel region.

16. The array substrate according to claim 13, wherein a material of the active layer comprises metal oxide.

17. The array substrate according to claim 13, wherein the buffer region has a width of 0.5 μm-1.5 μm.
